(19) United States
(12) Patent Application Publication
(10) Pub. No.: US 2019/0384091 A1
(43) Pub. Date: Dec. 19, 2019

(54) NARROW FRAME DISPLAY PANEL AND MANUFACTURING METHOD THEREOF, AND DISPLAY DEVICE

(71) Applicant: Wuhan China Star Optoelectronics Technology Co., Ltd, Wuhan, Hubei (CN)

(72) Inventors: Dejiun LI, Wuhan, Hubei (CN); Hongqing CUI, Wuhan, Hubei (CN); Wenqing SONG, Wuhan, Hubei (CN)

(21) Appl. No.: 15/579,179

(22) PCT Filed: Nov. 14, 2017
(86) PCT No.: PCT/CN2017/110866

§ 371 Date: Dec. 1, 2017

(30) Foreign Application Priority Data
Oct. 31, 2017 (CN) 201711053810.3

(51) Int. Cl. G02F 1/1333; G02F 1/1362; G02F 1/1345

(52) U.S. Cl. CPC G02F 1/133308; G02F 2001/136222; G02F 1/1345; G02F 1/136209

(57) ABSTRACT

The disclosure discloses a narrow frame display panel and a manufacturing method of thereof. The narrow frame display panel includes an array substrate, an opposite substrate, a liquid crystal filled between the array substrate and the opposite substrate, a flexible circuit board and a driving chip; a side located by the array substrate is a light emitting surface, one end of the array substrate is a binding end; one end of the flexible circuit board is bound to a surface of the binding end facing the opposite substrate, and the other end of the flexible circuit board is bound to the driving chip, a metal film layer with a hollow pattern is arranged on a surface of the array substrate facing the opposite substrate, a plurality of spaced columns are convexly arranged on a surface of the opposite substrate facing the array substrate, and the spaced columns extend to abut the metal film layer.

### RELATED APPLICATIONS

The present application is a National Phase of International Application Number PCT/CN2017/110866, filed Nov. 14, 2017, and claims the priority of China Application No. 201711053810.3 filed Oct. 31, 2017.

### BACKGROUND OF THE INVENTION

### 1. Field of the Invention

The disclosure relates to a narrow frame display panel and a manufacturing method thereof, and a display device.

### 2. The Related Arts

At present, the popularity of full-screen mobile phones is getting higher and higher, and the screen with high screen proportion is getting more and more popular. As a result, a lot of narrow frame solutions are created, and the narrow frame solutions mainly aim at the left and right frames, but regarding to the mobile phones, raising the proportion of screen-to-body ratio to the lower frame is a big topic. The so-called screen-to-body ratio is the ratio of the screen area to the mobile phones area. A higher proportion of the screen-to-body ratio may bring a better visual experience to the user. The flexible OLED display screen is a key element capable of achieving the hyperbolic design currently. With the increasingly mature of the flexible OLED technology, industrial design and physical form of the mobile phones in the future are bound to bring more innovation and changes.

Therefore, many manufacturers have adopted a COF (chip on film) scheme of a lower frame of the display reducing the width of the lower frame and improving the screen ratio Comparing with the conventional chip on glass (COG) design. However, the COF scheme also has many problems. For example, a chip (IC) is bonded to a flexible printed circuit (FPC), so that the space occupied by the array substrate of the frame for bonding the chip may be saved, resulting in a narrower lower frame.

However, since the FPC is bound to a surface of the array substrate facing the opposite substrate in a typical display adopting a COF scheme, a front frame needs to be designed for the display to shield a bonding end. Though it plays esthetic effects, it causes the bonding end of the display always having a certain frame width and affects the narrow frame of the display.

### SUMMARY

In view of the deficiencies of the prior art, the present disclosure provides a narrow frame display panel, a manufacturing method thereof, and a display device with a narrow frame and aesthetics, and the manufacturing precision of the products may be improved.

In order to achieve the above objects, the present disclosure adopts the following technical solutions.

A narrow frame display panel includes an array substrate, an opposite substrate, a liquid crystal filled between the array substrate and the opposite substrate, a flexible circuit board and a driving chip; wherein a side located by the array substrate is a light emitting surface, one end of the array substrate is a binding end; one end of the flexible circuit board is bound to a surface of the binding end facing the opposite substrate, and the other end of the flexible circuit board is bound to the driving chip, a metal film layer with a hollow pattern is arranged on a surface of the array substrate facing the opposite substrate, a plurality of spaced columns are convexly arranged on a surface of the opposite substrate facing the array substrate, and the spaced columns extend to abut the metal film layer.

As an embodiment of the disclosure, a cross section of the spaced column in a direction perpendicular to the opposite substrate is a trapezoid, and the closer to the metal film, the narrower the spaced column.

As an embodiment of the disclosure, a color resistance layer having color resistance with a plurality of colors is arranged on a surface of the array substrate facing away from the opposite substrate, a projection of the color resistance of the color resistance layer on the metal film layer is located in a hollow area of the metal film layer.

As an embodiment of the disclosure, a black shielding layer is further arranged on a surface of the array substrate facing away from the opposite substrate, the black shielding layer is arranged adjacent to the color resistance layer, and a projection of a pattern of the black shielding layer on the array substrate completely shields the metal film layer.

As an embodiment of the disclosure, the narrow frame display panel further includes a transparent flat layer, the flat layer being arranged on a surface of the array substrate and completely covering the black shielding layer and the color resistance layer.

Another object of the disclosure is to provide a manufacturing method of a narrow frame display panel, and the method includes:

manufacturing the array substrate, and forming a metal film layer with a hollow pattern on a side located by a thin film transistor of the array substrate;

making a plurality of the spaced column on one surface of the opposite substrate;

assembling the array substrate and the opposite substrate, and abutting an end of the spaced column on a corresponding part of the metal film layer.

As an embodiment of the disclosure, the manufacturing method of the narrow frame display panel further includes:

turning the array substrate over with an outer surface of the array substrate facing upward;

forming a color resistance layer and the black shielding layer on the array substrate, and covering surfaces of the black shielding layer and the color resistance layer with the flat layer.

Another object of the disclosure is to provide a display device, including a backlight module and a narrow frame display panel, the backlight module being arranged on a side located by the opposite substrate.

As an embodiment of the disclosure, the backlight module includes a reflection sheet, a light guide plate, a set of an optical film sheet and a light source from bottom to top; and the light source is arranged on the side of the light guide plate and provides a backlight for the light guide plate, and a projection of the light source in a direction perpendicular to the reflection sheet is located on the reflection sheet.

As an embodiment of the disclosure, the display device further includes a plastic frame, the light source including a substrate and LED lamp beads arranged on a surface of the substrate, the plastic frame arranged on the reflection sheet and spaced from the light guide plate, wherein the LED lamp beads are arranged in a gap between the plastic frame and the light guide plate, and two ends of the substrate are respectively attached to an upper surface of the light guide plate and the plastic frame.

In the disclosure, one end of a flexible circuit board is bound to a surface of the bonding end facing the opposite substrate, the other end of the flexible circuit board is bound with a driving chip and arranged opposite to the opposite substrate after being bent away from the light-exiting surface. Thus the flexible circuit board may not be seen outside the display panel. Therefore, the width of the frame may be reduced and the screen-to-body ratio may be increased. Simultaneously, the spaced column abutting the corresponding part of the hollow pattern of the metal film layer on the inner side of the array substrate may auxiliarily achieve the realization of the assembly process of the substrate of the display panel and improve an assembly precision.

### BRIEF DESCRIPTION OF THE DRAWINGS

FIG. 1 is a schematic structural view of a narrow frame display panel according to an embodiment of the present disclosure;

FIG, 2 is a schematic structural view of a display device according to an embodiment of the present disclosure;

FIG. 3 is a schematic view of a main manufacturing method a narrow frame display panel according to an embodiment of the present disclosure.

### DETAILED DESCRIPTION OF THE PREFERRED EMBODIMENTS

In order to make the objectives, technical schemes and advantages of the disclosure more comprehensible, the disclosure is further described in detail below with reference to the accompanying drawings and embodiments. It should be understood that the specific embodiments described herein are merely used to explain the disclosure, and are not intended to limit the disclosure.

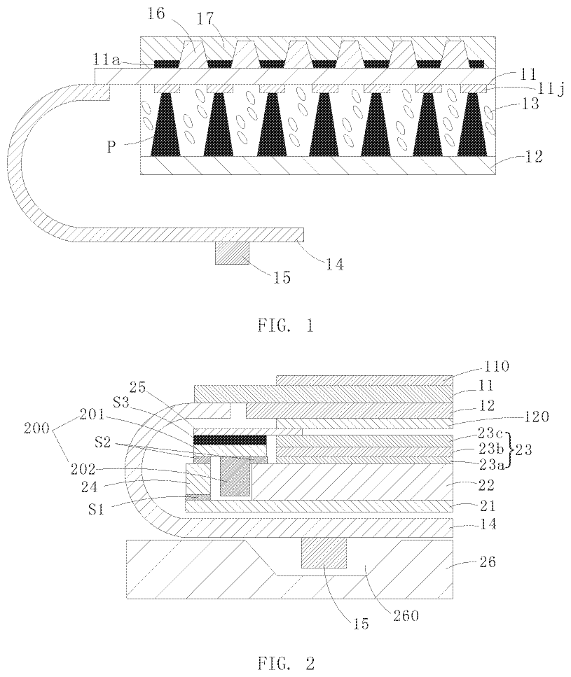

Refer to FIGS. 1 and 2, a narrow frame display panel according to an embodiment of the present disclosure mainly includes an array substrate 11, an opposite substrate 12, a liquid crystal 13 filled between the array substrate 11 and the opposite substrate 12, a flexible circuit board 14 and a driving chip 15. Wherein a side located by the array substrate 11 is a light emitting surface, the backlight source emits a light from the side located by the opposite substrate 12. One end of the array substrate 11 is a binding end; one end of the flexible circuit board 14 is bound to a surface of the binding end facing the opposite substrate 12, and the other end of the flexible circuit board 14 is bound to the driving chip 15. The upper polarizer 110 and the lower polarizer 120 are respectively attached to outer surfaces of the array substrate 11 and the opposite substrate 12. The backlight light enters into the liquid crystal 13 after being deflected by the lower polarizer 120, and is deflected by the upper polarizer 110 again and then emits. A metal film layer 11j with a hollow pattern is arranged on a surface of the array substrate 11 facing the opposite substrate 12, a plurality of spaced columns P are convexly arranged on a surface of the opposite substrate 12 facing the array substrate 11, and the spaced columns P extend to abut the metal film layer 11j.

Due to the spaced column P on the opposite substrate 12 abutting on the corresponding part of the hollow pattern of the metal film layer 11j on the inner side of the array substrate 11. Therefore, when assembling, the relative position relationship between the metal film layer 11j and an end of the spaced column P may be used as a reference for the assembly. It may auxiliarily achieve the assembly process of the substrate of the display panel and improve the assembly precision.

In the conventional technology, if the side located by the opposite substrate 12 is used as the light-emitting surface of the display panel, the lower surface of one end of the flexible circuit board 14 needs to be bound to the binding end of the array substrate 11, and the driving chip 15 needs to be bound to the upper surface of the other end of the flexible circuit board 14, so as to ensure that one end located by the driving chip 15 is oppositely bent and the driving chip 15 is subsequently away from the reflection sheet. It causes the flexible circuit board 14 being made by laminating at least two layers of COF, and having no cost advantages. Moreover, the binding end faces the viewer. So the shielded front frame needs to be made to achieve aesthetics, and the frame of the bonding end may not be narrowed. In the embodiment, because the bonding end and the driving chip 15 are simultaneously conducted with the same surface of a single layer of the chip on film, the flexible circuit board 14 may adopt the single layer of chip on film (COF), thereby greatly reducing the cost. It also guarantees the optical quality, simultaneously achieves the real frameless design of the side located by the bonding end.

Comparing with the opposite substrate 12, one end of the array substrate 11 is relatively longer, and an edge portion of the end located outside the non-display area serves as a binding end. One end of the flexible circuit board 14 is bound to a surface of the binding end facing the opposite substrate 12 (i.e., a lower surface as shown in FIG,1). The other end of the flexible circuit board 14 is bound with a driving chip 15 and arranged opposite to the opposite substrate 12 after being bent away from the light-exiting surface. After the flexible circuit board 14 is bent, the driving chip 15 is located on the side of the flexible circuit board 14 facing away from the opposite substrate 12. Therefore, after light guide plates and reflection sheets and the like of the backlight module are assembled between the opposite substrate 12 and the flexible circuit board 14, the driving chip is away from the reflection sheet of the backlight module, ensuring the optical quality, and at the same time avoiding a heated driving chip affecting the heat dissipation of the reflection sheet.

As an embodiment, a cross section of the spaced column P in a direction perpendicular to the opposite substrate 12 is a trapezoid, and the closer to the metal film 11j, the narrower the spaced column P. Specifically, the spaced column P may be a circular truncated cone or a frustum of a pyramid. This may ensure a uniform cell thickness of the display panel after assembly.

On the surface of the array substrate 11 facing away from the opposite substrate 12, a color resistance layer 16 is formed by color resistances with a plurality of colors, and respective color resistance is spaced apart and arranged regularly, for example, in a circular arrangement of R, G, B, R, G and B. a projection of the color resistance of the color resistance layer 16 on the metal film layer 11j is located in a hollow area of the metal film layer, so that a light emitted by the liquid crystal may be emitted toward the color resistance.

On a surface of the array substrate 11 facing away from the opposite substrate 12, the black shielding layer 11a is arranged adjacent to the color resistance layer to shield a gap between the color resistances, and a projection of a pattern of the black shielding layer 11a on the array substrate 11 completely shields the metal film layer 11j. Therefore, the viewer may not see the metal film layer 11j from the outside and this does not affect the viewing experience.

On the side facing the viewer, the display panel is further provided with a transparent flat layer 17. The flat layer 17 is arranged on a surface of the array substrate 11 and completely covers the black shielding layer 11a and the color resistance layer 16. On the one hand, it may protect the black shielding layer 11a and the color resistance layer 16. On the other hand, it may ensure the display panel having a flat display surface.

It should be noted that in the embodiment, the opposite substrate 12 is substantially different from a conventional opposite substrate. The opposite substrate in the embodiment may be just an ordinary glass substrate and has no structure such as a color filter and a black matrix and the like on its surface.

In combination with FIG. 2, the display device provided by the disclosure includes a backlight module and the narrow frame display panel. The backlight module is arranged on the side of the opposite substrate 12 (as shown in FIG. 2). The backlight module mainly includes a reflection sheet 21, a light guide plate 22, a set of an optical film 23 and a light source 200 from bottom to top, and the light source is arranged on the light guide plate 22 and provides a backlight for the light guide plate 22. A projection of the light source 200 in a direction perpendicular to the direction of the reflection sheet 21 reflection is located in the reflection sheet 21. In this way, the reflection sheet 21 may reflect light emitted by the light source 200 to the maximum extent, thereby improving light utilization and avoiding light leakage near the light guide plate 22.

In the embodiment, the display device may further include a plastic frame 24, a light shielding sheet 25 and a middle frame 26. The light source 200 includes a substrate 201 and LED lamp beads 202 arranged on the surface of the substrate 201. The plastic frame 24 is arranged on the reflection sheet 21 and arranged spaced from the light guide plate. The LED lamp beads 202 are arranged in a gap between the plastic frame 24 and the light guide plate 22, and two ends of the substrate 201 are respectively attached to the upper surface of the light guide plate and the plastic frame. The light-shielding sheet 25 is attached to an upper surface of the substrate 201 and extends to partially cover an edge of the set of an optical film 23, completely preventing the light leakage above a side of light source where the light guide plate is located. A groove 260 is formed in the inner surface of the middle frame 26, the flexible circuit board 14 is directly opposite to the middle frame 26, and the driving chip 15 is housed in the groove 260, so as to further reduce the thickness of the display device and protect the driving chip 15.

The set of an optical film 23 is composed of three optical film layers. The set of an optical film 23 includes a lower prism layer 23a, a diffusion layer 23b and an upper prism layer 23c which are sequentially stacked from bottom to top. A lower surface of the plastic frame 24 is attached on the protruding portion of the reflection sheet 21 by an optical adhesive S1. An upper surface of the plastic frame 24 and an upper surface edge of the light guide plate 22 are respectively adhered with the substrate 201 by another optical adhesive S2. Here, the optical plastic S1, the other optical adhesive S2 are made of light-absorbing material, so as to avoid light leakage there. The light-shielding sheet 25 is attached to an upper surface of the substrate 201 by double-sided adhesive.

Since the narrow frame display panel of the display device of the embodiment may omit the frame for shielding the binding end, the bonding end of the display device may be frameless and a screen-to-body ratio may be improved.

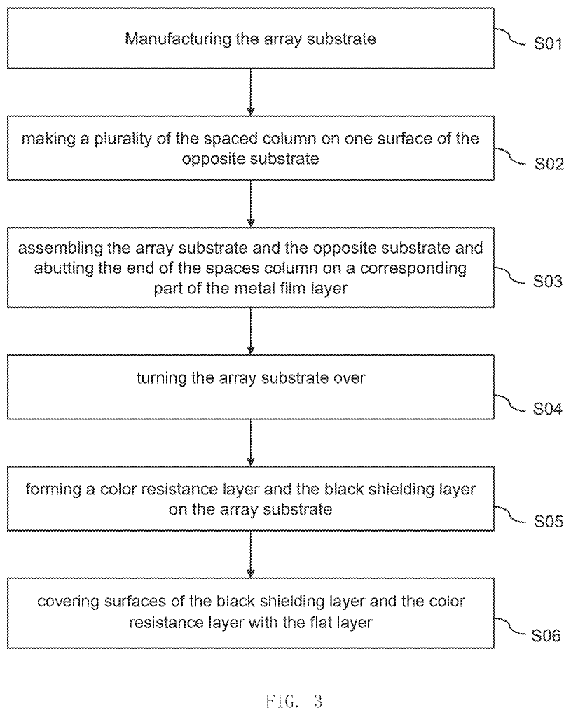

As shown in FIG. 3, a manufacturing method of the narrow frame display panel of the embodiment mainly includes:

S01: manufacturing the array substrate 11, and forming a metal film layer 11j with a hollow pattern on a side located by a thin film transistor of the array substrate 11;

S02: making a plurality of the spaced column P on one surface of the opposite substrate 12, so as to make the spaced column P evenly arrange on the surface of the opposite substrate 12;

S03: assembling the array substrate 11 and the opposite substrate 12, and abutting an end of the spaced column P on a corresponding part of the metal film layer 11j.

After the array substrate 11 and the opposite substrate 12 are assembled, the method further includes:

S04: turning the array substrate 11 over h an outer surface of the array substrate 11 facing upward;

S05: forming a color resistance layer 16 and the black shielding layer 11a on the array substrate 11; and

S06: covering surfaces of the black shielding layer 11 a and the color resistance layer 16 with the flat layer 17.

When the color resistance layer 16 and the black shielding layer 11 are manufactured, the color resistance layer 16 and the black shielding layer 11 are sequentially formed on the array substrate 11. That is, after the color resistance layer 16 is completed, a black shielding layer 11a is filled between the color resistances of the color resistance layer 16. Here, the color resistance layer 16 and the spaced column P are both manufactured by covering the shielding plate. The color resistance layer 16 with a specific pattern is formed after forming a film, exposing, developing and etching successively.

In the disclosure, on the one hand, a relative position relationship between a metal film layer 11j and an end of the spaced column P may be used as a reference for the assembly. On the other hand, the RGB color resistance layer 16 is manufactured on the outer surface of the array substrate 11 assembled. Comparing with the assembly error, a precision error caused by the manufacturing process of the color resistance layer may be less. This may obviously reduce the influence on an aperture ratio of pixel and enhance a luminous efficiency.

In the disclosure, one end of a flexible circuit board is bound to a surface of the bonding end facing the opposite substrate, the other end of the flexible circuit board is bound with a driving chip and arranged opposite to the opposite substrate after being bent away from the light-exiting surface. Thus the flexible circuit board may not be seen outside the display panel. Therefore, the width of the frame may be reduced and the screen-to-body ratio may be increased. Meanwhile, the driving chip is located on a side of the flexible circuit board facing away from the opposite substrate, and therefore may be away from the heated reflection sheet of the backlight module, and this ensures an optical quality without increasing the thickness of the display device. In addition, the black shielding layer on the outer surface of the array substrate may prevent the ambient light from illuminating metal film layer on the inner surface of the array substrate to prevent specular reflection. In addition, the manufacturing precision of the display device is significantly improved. This may be helpful to reduce the influence on an aperture ratio of pixel and enhance a luminous efficiency.

The above descriptions are merely specific embodiments of the present application. It should be noted that those skilled in the art may make some improvements and modifications without departing from the principle of the present application. These improvements and modifications should also be regarded as within the protection scope of this application.

What is claimed is:

1. A narrow frame display panel, comprising an array substrate, an opposite substrate, a liquid crystal filled between the array substrate and the opposite substrate, a flexible circuit board and a driving chip; wherein a side located by the array substrate is a light emitting surface, one end of the array substrate is a binding end; one end of the flexible circuit board is bound to a surface of the binding end facing the opposite substrate, and the other end of the flexible circuit board is bound to the driving chip, a metal film layer with a hollow pattern is arranged on a surface of the array substrate facing the opposite substrate, a plurality of spaced columns are convexly arranged on a surface of the opposite substrate facing the array substrate, and the spaced columns extend to abut the metal film layer.

2. The narrow frame display panel according to claim 1, wherein a cross section of the spaced column in a direction perpendicular to the opposite substrate is a trapezoid, and the closer to the metal film, the narrower the spaced column.

3. The narrow frame display panel according to claim 1, wherein a color resistance layer having color resistance with a plurality of colors is arranged on a surface of the array substrate facing away from the opposite substrate, a projection of the color resistance of the color resistance layer on the metal film layer is located in a hollow area of the metal film layer.

4. The narrow frame display panel according to claim 3, wherein a black shielding layer is further arranged on a surface of the array substrate facing away from the opposite substrate, the black shielding layer is arranged adjacent to the color resistance layer, and a projection of a pattern of the black shielding layer on the array substrate completely shields the metal film layer.

5. The narrow frame display panel according to claim 4, further comprising a transparent flat layer, the flat layer being arranged on a surface of the array substrate and completely covering the black shielding layer and the color resistance layer.

6. The narrow frame display panel according to claim 2, wherein a color resistance layer having color resistance with a plurality of colors is arranged on a surface of the array substrate facing away from the opposite substrate, a projection of the color resistance of the color resistance layer on the metal film layer is located in a hollow area of the metal film layer.

7. The narrow frame display panel according to claim 6, wherein a black shielding layer is further arranged on a surface of the array substrate facing away from the opposite substrate, the black shielding layer is arranged adjacent to the color resistance layer, and a projection of a pattern of the black shielding layer on the array substrate completely shields the metal film layer.

8. The narrow frame display panel according to claim 7, further comprising a transparent flat layer, the flat layer being arranged on a surface of the array substrate and completely covering the black shielding layer and the color resistance layer.

9. A manufacturing method of a narrow frame display panel, wherein the narrow frame display panel comprises an array substrate, an opposite substrate, a liquid crystal filled between the array substrate and the opposite substrate, a flexible circuit board and a driving chip; a side located by the array substrate is a light emitting surface, one end of the array substrate is a binding end; one end of the flexible circuit board is bound to a surface of the binding end facing the opposite substrate, and the other end of the flexible circuit board is bound to the driving chip, a metal film layer with a hollow pattern is arranged on a surface of the array substrate facing the opposite substrate, a plurality of spaced columns are convexly arranged on a surface of the opposite substrate facing the array substrate, and the spaced columns extend to abut the metal film layer; the manufacturing method of the narrow frame display panel comprises:
manufacturing the array substrate, and forming a metal film layer with a hollow pattern on a side located by a thin film transistor of the array substrate;
making a plurality of the spaced columns on one surface of the opposite substrate;
assembling the array substrate and the opposite substrate, and abutting an end of the spaced column on a corresponding part of the metal film layer.

10. The manufacturing method of the narrow frame display panel according to claim 9, further comprising:
turning the array substrate over with an outer surface of the array substrate facing upward;
forming a color resistance layer and a black shielding layer on the array substrate, and covering surfaces of the black shielding layer and the color resistance layer with the flat layer.

11. The manufacturing method of the narrow frame display panel according to claim 10, wherein a cross section of the spaced column in a direction perpendicular to the opposite substrate is a trapezoid, and the closer to the metal film, the narrower the spaced column.

12. The manufacturing method of the narrow frame display panel according to claim 10, wherein the color resistance layer having color resistance with a plurality of colors is arranged on a surface of the array substrate facing away from the opposite substrate, a projection of the color resistance of the color resistance layer on the metal film layer is located in a hollow area of the metal film layer.

13. A display device, wherein the display device comprises a backlight module and a narrow frame display panel, the narrow frame display panel comprises an array substrate, an opposite substrate, a liquid crystal filled between the array substrate and the opposite substrate, a flexible circuit board and a driving chip; a side located by the array substrate is a light emitting surface, one end of the array substrate is a binding end; one end of the flexible circuit board is bound to a surface of the binding end facing the opposite substrate, and the other end of the flexible circuit board is bound to the driving chip, a metal film layer with a hollow pattern is arranged on a surface of the array substrate facing the opposite substrate, a plurality of spaced columns are convexly arranged on a surface of the opposite substrate facing the array substrate, and the spaced columns extend to abut the metal film layer; and the backlight module is arranged on a side located by the opposite substrate.

14. The display device according to claim 13, wherein the backlight module comprises a reflection sheet, a light guide plate, a set of an optical film sheet and a light source from bottom to top, the light source is arranged on the side of the light guide plate and provides a backlight for the light guide plate, and a projection of the light source in a direction perpendicular to the reflection sheet is located on the reflection sheet.

15. The display device according to claim 14, further comprising a plastic frame, the light source comprising a substrate and LED lamp beads arranged on a surface of the substrate, the plastic frame arranged on the reflection sheet and spaced from the light guide plate, wherein the LED lamp beads are arranged in a gap between the plastic frame and the light guide plate, and two ends of the substrate are respectively attached to an upper surface of the light guide plate and the plastic frame.

16. The display device according to claim 13, wherein a cross section of the spaced column in a direction perpendicular to the opposite substrate is a trapezoid, and the closer to the metal film, the narrower the spaced column.

17. The display device according to claim 13, a color resistance layer having color resistance with a plurality of colors is arranged on a surface of the array substrate facing away from the opposite substrate, a projection of the color resistance of the color resistance layer on the metal film layer is located in a hollow area of the metal film layer.

18. The display device according to claim 17, wherein a black shielding layer is further arranged on a surface of the array substrate facing away from the opposite substrate, the black shielding layer is arranged adjacent to the color resistance layer, and a projection of a pattern of the black shielding layer on the array substrate completely shields the metal film layer.

19. The display device according to claim 18, the narrow frame display panel further comprises a transparent flat layer, the flat layer is arranged on a surface of the array substrate and completely covers the black shielding layer and the color resistance layer.

20. The display device of claim 16, wherein a black shielding layer is further arranged on a surface of the array substrate facing away from the opposite substrate, the black shielding layer is arranged adjacent to the color resistance layer, and a projection of a pattern of the black shielding layer on the array substrate completely shields the metal film layer.
